(19) United States
(12) Patent Application Publication
(10) Pub. No.: US 2021/0184168 A1
(43) Pub. Date: Jun. 17, 2021

(54) OLED DISPLAY AND MANUFACTURING METHOD THEREOF

(71) Applicant: WUHAN CHINA STAR OPTOELECTRONICS SEMICONDUCTOR DISPLAY TECHNOLOGY CO., LTD., Wuhan, Hubei (CN)

(72) Inventor: Xuebing YIN, Wuhan, Hubei (CN)

(21) Appl. No.: 16/761,537

(22) PCT Filed: Jan. 2, 2020
(86) PCT No.: PCT/CN2020/070083

§ 371 Date: May 5, 2020

(30) Foreign Application Priority Data
Dec. 16, 2019 (CN) 201911289918.1

(51) Int. Cl. H01L 51/52; H01L 51/56

(52) U.S. Cl. CPC H01L 51/5253; H01L 27/3244; H01L 51/56

(57) ABSTRACT

The present invention discloses an OLED display and a manufacturing method thereof. The OLED display includes a substrate, a barrier layer, a TFT driving circuit, an insulating layer, an organic light-emitting layer and an encapsulating layer. The barrier layer has a reversed trapezoid structure. The organic light-emitting layer breaks at the reversed trapezoid structure. By the reversed trapezoid structure, the organic light-emitting film layer automatically breaks at the reversed trapezoid structure in a flat layer such that a path of lateral invasion of moisture and oxygen is cut away. After encapsulation is completed, a through hole is formed by laser cutting, which greatly reduces manufacturing difficulty.

### FIELD OF THE DISCLOSURE

The present invention relates to display technologies, and more particularly to an organic light emitting diode (OLED) display and a manufacturing method thereof.

### DESCRIPTION OF RELATED ARTS

Display panels, such as organic light-emitting diode (OLED for short) display panels, have received great attention from academics and industry because of their tremendous potential in solid-state lighting and flat-panel displaying. OLED display panels can be made lighter and thinner, so flexible display technologies will be the future.

The biggest advantage of OLED displays is that they can realize flexible displays. Flexible displays are presented in various ways, such as curved screens, bendable screens, rollable screens, and etc. At the same time, improving a screen-to-body ratio has also become a trend of display technologies, especially for mobile displays. Therefore, the design of display screens has also gone through a track of evolution from trenching, V-grooving, waterdrop notch, and O-shaped punch design, in which it has the greatest difficulty in designing and manufacturing a display screen with the O-shaped punch.

### TECHNICAL PROBLEMS

The present invention provides a structural design and a manufacturing method of an OLED display, in which a reversed trapezoid structure designed in a non-display region of the OLED display can effectively interrupt continuity of an organic light-emitting layer in the non-display region, thereby carrying out a design of a through hole by laser cutting after encapsulation is completed. Since the organic layer does not have a direct connection to the outside, reliability of the screen is ensured.

### TECHNICAL SOLUTIONS

Technical solutions provided by the present invention are described below.

An embodiment of the present invention provides an OLED display including:

a substrate;

a barrier layer, disposed on the substrate, the barrier layer and the substrate having a through hole penetrating the barrier layer and the substrate, the barrier layer having a reversed trapezoid structure;

a thin-film transistor (TFT) driving circuit, disposed on the barrier layer, the TFT driving circuit including a plurality of TFT electrodes surrounding the through hole, the TFT driving circuit having no TFT electrodes in the through hole;

an insulating layer, disposed on the TFT driving circuit, the insulating layer including an opening for exposing the through hole;

an organic light-emitting layer, disposed on the insulating layer; and

an encapsulating layer, disposed on the organic light-emitting layer,

wherein the organic light-emitting layer breaks at the reversed trapezoid structure to form a discontinuous film layer,

wherein a length of an upper edge of the reversed trapezoid structure is greater than a length of a lower edge of the reversed trapezoid structure, and a thickness of the organic light-emitting layer is less than a thickness of the reversed trapezoid structure.

In the OLED display provided according to an embodiment of the present invention, the substrate has a perforated region corresponding to the through hole, a display region corresponding to the TFT driving circuit and a non-display region located between the perforated region and the display region, and wherein the reversed trapezoid structure is located in the non-display region.

In the OLED display provided according to an embodiment of the present invention, the TFT driving circuit, the insulating layer and the organic light-emitting layer break at the reversed trapezoid structure to form an opening.

In the OLED display provided according to an embodiment of the present invention, the encapsulating layer completely covers the reversed trapezoid structure and the opening formed at the reversed trapezoid structure by the TFT driving circuit, the insulating layer and the organic light-emitting layer.

In the OLED display provided according to an embodiment of the present invention, a crack-preventing structure is disposed above the barrier layer and is located in the non-display region close to the perforated region.

In the OLED display provided according to an embodiment of the present invention, the crack-preventing structure and the insulating layer use a same material.

In the OLED display provided according to an embodiment of the present invention, a thickness of the reversed trapezoid structure is ranged from 0.5 to 1 micrometer and an angle θ inclined from a bottom of the reversed trapezoid structure is ranged from 120 to 150 degrees.

An embodiment of the present invention further provides an OLED display including:

a substrate;

a barrier layer, disposed on the substrate, the barrier layer and the substrate having a through hole penetrating the barrier layer and the substrate, the barrier layer having a reversed trapezoid structure;

a thin-film transistor (TFT) driving circuit, disposed on the barrier layer, the TFT driving circuit including a plurality of TFT electrodes surrounding the through hole, the TFT driving circuit having no TFT electrodes in the through hole;

an insulating layer, disposed on the TFT driving circuit, the insulating layer including an opening for exposing the through hole;

an organic light-emitting layer, disposed on the insulating layer; and

an encapsulating layer, disposed on the organic light-emitting layer,

wherein the organic light-emitting layer breaks at the reversed trapezoid structure to form a discontinuous film layer.

In the OLED display provided according to an embodiment of the present invention, the substrate has a perforated region corresponding to the through hole, a display region corresponding to the TFT driving circuit and a non-display region located between the perforated region and the display region, and wherein the reversed trapezoid structure is located in the non-display region.

In the OLED display provided according to an embodiment of the present invention, the TFT driving circuit, the insulating layer and the organic light-emitting layer break at the reversed trapezoid structure to form an opening.

In the OLED display provided according to an embodiment of the present invention, the encapsulating layer completely covers the reversed trapezoid structure and the opening formed at the reversed trapezoid structure by the TFT driving circuit, the insulating layer and the organic light-emitting layer.

In the OLED display provided according to an embodiment of the present invention, a crack-preventing structure is disposed above the barrier layer and is located in the non-display region close to the perforated region.

In the OLED display provided according to an embodiment of the present invention, the crack-preventing structure and the insulating layer use a same material.

In the OLED display provided according to an embodiment of the present invention, a length of an upper edge of the reversed trapezoid structure is greater than a length of a lower edge of the reversed trapezoid structure.

In the OLED display provided according to an embodiment of the present invention, a thickness of the reversed trapezoid structure is ranged from 0.5 to 1 micrometer and an angle θ inclined from a bottom of the reversed trapezoid structure is ranged from 120 to 150 degrees.

In the OLED display provided according to an embodiment of the present invention, a thickness of the organic light-emitting layer is less than a thickness of the reversed trapezoid structure.

An embodiment of the present invention further provides a method for manufacturing an OLED display, which includes:

S1, forming a barrier layer on a substrate, the substrate having a display region, a perforated region and a non-display region located between the display region and the perforated region;

S2, forming a reversed trapezoid structure on the barrier layer in the non-display region;

S3, manufacturing a thin-film transistor driving circuit in the display region of the substrate, the TFT driving circuit including a plurality of TFT electrodes surrounding a through hole and forming an opening in the non-display region;

S4, forming an insulating layer on the TFT driving circuit, the insulating layer forming the opening in the non-display region;

S5, forming an organic light-emitting layer on the insulating layer, the organic light-emitting layer breaking at the reversed trapezoid structure to form a discontinuous film layer, the organic light-emitting layer forming the opening in the non-display region; and

S6, covering the TFT driving circuit, the insulating layer and the organic light-emitting layer with an encapsulating layer.

### BENEFICIAL EFFECTS

A design of perforation is adopted in the display. A camera is disposed below a perforated region. This can improve a screen-to-body ratio. By the reversed trapezoid structure, the organic light-emitting film layer automatically breaks at the reversed trapezoid structure in a flat layer such that a path of lateral invasion of moisture and oxygen is cut away. After encapsulation is completed, a through hole is formed by removing the perforated region by laser cutting, which greatly reduces manufacturing difficulty.

### DESCRIPTION OF DRAWINGS

For explaining the technical solutions used in the existing arts or the embodiments more clearly, the appended figures to be used in describing the existing arts or the embodiments will be briefly introduced in the following. Obviously, the appended figures described below are only some of the embodiments of the invention, and those of ordinary skill in the art can further obtain other figures according to these figures without making any inventive effort.

FIG. 1 is a structural schematic diagram showing an OLED display provided in an embodiment of the present invention.

FIG. 2 is a first one of flowcharts of a method for manufacturing the OLED display provided in an embodiment of the present invention.

FIG. 3 is a second one of flowcharts of a method for manufacturing the OLED display provided in an embodiment of the present invention.

FIG. 4 is a third one of flowcharts of a method for manufacturing the OLED display provided in an embodiment of the present invention.

FIG. 5 is a fourth one of flowcharts of a method for manufacturing the OLED display provided in an embodiment of the present invention.

FIG. 6 is a fifth one of flowcharts of a method for manufacturing the OLED display provided in an embodiment of the present invention.

### DESCRIPTION OF EMBODIMENTS OF THE DISCLOSURE

The technical solutions in the embodiments of the present application will be clearly and completely described below with reference to appended drawings of the embodiments of the present application. Obviously, the described embodiments are merely a part of embodiments of the present application and are not all of the embodiments. Based on the embodiments of the present application, all the other embodiments obtained by those of ordinary skill in the art without making any inventive effort are within the scope the present application.

In the description of the present application, it is to be understood that the terms “center”, “longitudinal”, “lateral”, “length”, “width”, “thickness”, “upper”, “lower”, “front”, “rear”, “left”, “right”, “vertical”, “horizontal”, “top”, “bottom”, “inner”, “outer”, “clockwise”, “counterclockwise” and the like indicated orientation or positional relationship are based on the relationship of the position or orientation shown in the drawings, which is only for the purpose of facilitating description of the present application and simplifying the description, but is not intended to or implied that the device or element referred to must have a specific orientation, and be constructed and operated in a particular orientation. Therefore, it should not be construed as a limitation of the present application. In addition, the terms “first” and “second” are used for descriptive purposes only, and should not be taken to indicate or imply relative importance, or implicitly indicate the indicated number of technical features. Thus, by defining a feature with “first” or “second”, it may explicitly or implicitly include one or more features. In the description of the present application, “a plurality” means two or more unless explicitly defined.

In the description of the present application, it should be noted that unless otherwise explicitly specified or limited, the terms “installed”, “connected”, and “connection” should be construed broadly, for example, a fixed connection, a removable connection, or integrally connected. These terms may be a mechanical connection, and may also be an electrical connection or communication. Moreover, these terms can be directly attached, be indirectly connected through an intermediate medium, and may be internally communicated with two components or the interaction relationship between two components. For persons skilled in the art, they can understand the specific meaning of the terms in the present application based on specific conditions.

In the present application, unless specified or limited otherwise, a structure in which a first feature is “on” or “below” a second feature may include an embodiment in which the first feature is in direct contact with the second feature, and may also include an embodiment in which the first feature and the second feature are not in direct contact with each other, but are contacted via an additional feature formed therebetween. Furthermore, a first feature “on,” “above,” or “on top of” a second feature may include an embodiment in which the first feature is right or obliquely “on,” “above,” or “on top of” the second feature, or just means that the first feature is at a height higher than that of the second feature; while a first feature “below,” “under,” or “on bottom of” a second feature may include an embodiment in which the first feature is right or obliquely “below,” “under,” or “on bottom of” the second feature, or just means that the first feature is at a height lower than that of the second feature.

The following disclosure provides a plurality of different embodiments or examples to implement different structures of this application. To simplify the disclosure of this application, the following describes components and settings in particular examples. Certainly, the examples are merely for illustrative purposes, and are not intended to limit this application. In addition, in this application, reference numerals and/or reference letters may be repeated in different examples. This repetition is for the purpose of simplicity and clarity, and does not in itself indicate a relationship between the various embodiments and/or settings that are discussed. In addition, this application provides examples of various particular processes and materials, but a person of ordinary skill in the art will recognize that other processes and/or materials may be applied and/or used.

An embodiment of the present invention provides an organic light emitting diode (OLED) display structure. As shown in FIG. 1, the OLED display has a perforated region 1 within Area A. A camera device is disposed below the perforated region 1. Accordingly, a screen-to-body ratio can be improved. The perforated region 1 is an O-shaped perforated region 1, for example.

The present embodiment provides an OLED display including a substrate;

a barrier layer, disposed on the substrate, the barrier layer and the substrate having a through hole penetrating the barrier layer and the substrate, the barrier layer having a reversed trapezoid structure;

a thin-film transistor (TFT) driving circuit, disposed on the barrier layer, the TFT driving circuit including a plurality of TFT electrodes surrounding the through hole, the TFT driving circuit having no TFT electrodes in the through hole;

an insulating layer, disposed on the TFT driving circuit, the insulating layer including an opening for exposing the through hole;

an organic light-emitting layer, disposed on the insulating layer; and

an encapsulating layer, disposed on the organic light-emitting layer,

wherein the organic light-emitting layer breaks at the reversed trapezoid structure to form a discontinuous film layer.

The substrate has a perforated region corresponding to the through hole, a display region corresponding to the TFT driving circuit and a non-display region located between the perforated region and the display region. The reversed trapezoid structure is located in the non-display region. Also, a thickness of the organic light-emitting layer is less than a thickness of the reversed trapezoid structure.

The OLED display structure includes a substrate 100, a buffer layer 201, a barrier layer 202 and a TFT driving circuit 200 disposed above the barrier layer 202, and further includes an organic light-emitting layer 300 disposed on the TFT driving circuit 202 and an encapsulating layer 400 covering the organic light-emitting layer 300. The encapsulating layer 400 includes a first inorganic barrier layer 401, an organic barrier layer 402 and a second inorganic barrier layer 403 that sequentially disposed on the organic light-emitting layer 300. The barrier layer 202 is a reversed trapezoid structure while in the O-shaped perforated region 1. A flattening layer 205 of the TFT driving circuit 200 is also a reversed trapezoid structure while in the O-shaped perforated region. The TFT driving circuit, the insulating layer and the organic light-emitting layer break at the reversed trapezoid structure to form an opening. The organic light-emitting layer 300 breaks at the reversed trapezoid structure of the barrier layer 202 and the flattening layer 205.

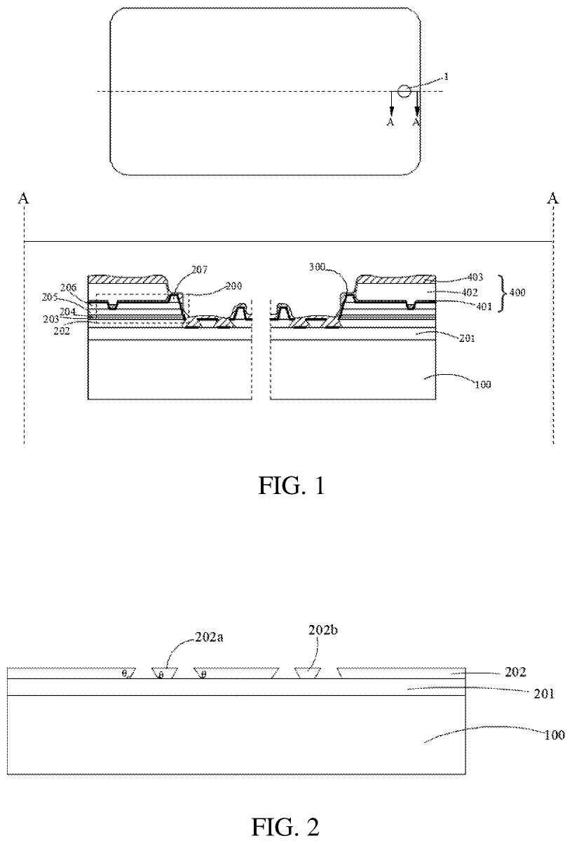

As shown in FIG. 2, the OLED display has a substrate 100, which is made of any one of polyimide, polyethylene terephthalate and polycarbonate. Then, the substrate 100 is covered by a buffer layer 201, a material of which is silicon oxide. A thickness of the buffer layer 201 is ranged from 0.5 to 1 micrometer. The buffer layer 201 plays a role to protect the substrate 100 and prevent from an invasion of moisture and oxygen. A barrier layer 202 is disposed above the buffer layer 201. A material of the barrier layer 202 is silicon oxide. A thickness of the barrier layer 202 is ranged from 0.5 to 1 micrometer. Two reversed trapezoid structures, a first reversed trapezoid structure 202a and a second reversed trapezoid structure 202b, are manufactured for the barrier layer 202 in the O-shaped perforated region 1 by exposure and development technologies. Bottom angles θ of the first reversed trapezoid structure 202a and the second reversed trapezoid structure 202b are ranged from 120 to 150 degrees. A length of an upper edge of the reversed trapezoid structure is greater than a length of a lower edge of the reversed trapezoid structure.

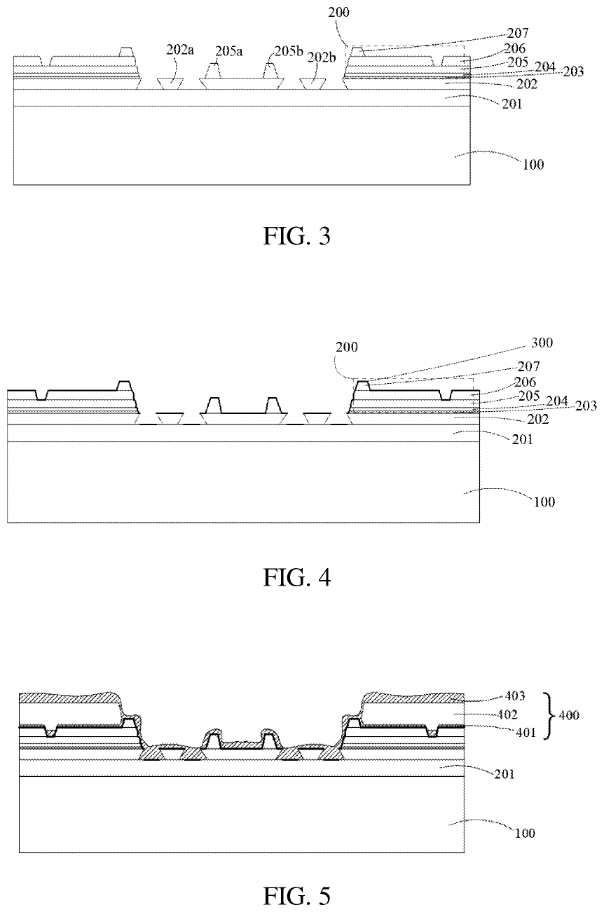

As shown in FIG. 3, the TFT driving circuit 200 is disposed above the barrier layer 202. The TFT driving circuit 200 at least includes a gate insulating layer 203, an insulating barrier layer 204, a flattening layer 205, a pixel definition layer 206 and a photoresist layer 207. The gate insulating layer 203 and the insulating barrier layer 204 are inorganic layers including any of silicon oxide and silicon nitride. The flattening layer 205, the pixel definition layer 206 and the photoresist layer 207 are organic layers. The flattening layer 205 has two trapezoid structures disposed in the O-shaped perforated region 1. The two trapezoid structures are a first trapezoid structure 205a and a second trapezoid structure 205. The first trapezoid structure 205a and the second trapezoid structure 205b serve as crack-preventing walls, which play a role of preventing from expansion of cracks during a cutting process. The crack-preventing structures are disposed above the barrier layer and is located in the non-display region close to the perforated region. The pixel definition layer 206 and the photoresist layer 207 are also provided with retaining structures for preventing from an overflow of a liquid of encapsulating substance during encapsulating the display. One or more retaining structures may be deployed for the pixel definition layer 206 and the photoresist layer 207 and the present embodiment is illustrated by one retaining structure. The crack-preventing structure and the insulating layer are made of a same material.

As shown in FIG. 4, an organic light-emitting layer 300 is coated on the TFT driving circuit 200 by evaporation. The organic light-emitting layer 300 includes a hole injection layer, a hole transmission layer, a light emitting layer, an electronic transmission layer, an electronic injection layer, a cathode, an optical cover layer and a lithium fluoride protective layer. Since the entire thickness of the organic light-emitting layer 300 is smaller than 0.4 micrometers, each functional layer of the organic light-emitting layer 300 are not shown in the figure. Moreover, the first reversed trapezoid structure 202a (not labeled in the figure) and the second trapezoid structure 202b (not labeled in the figure) are relatively special reversed trapezoid structures and the entire the organic light-emitting layer 300 is relatively small in thickness. Accordingly, when coating the organic light-emitting layer 300 by evaporation, the organic light-emitting layer 300 will break at the first reversed trapezoid structure 202a and the second reversed trapezoid structure 202b and will be avoided to form a continuous film layer.

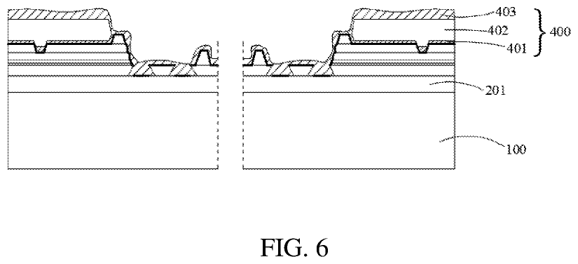

As shown in FIGS. 5 and 6, an encapsulating layer 400 is then manufactured on the organic light-emitting layer 300. The encapsulating layer completely covers the reversed trapezoid structure and the opening formed at the reversed trapezoid structure by the TFT driving circuit, the insulating layer and the organic light-emitting layer. The encapsulating layer 400 includes a first inorganic barrier layer 401, an organic barrier layer 402 and a second inorganic barrier layer 403. The organic light-emitting layer 300 is covered by the first inorganic barrier layer 401 for preventing from an invasion of moisture and oxygen. Then, the organic barrier layer 402 is manufactured on the first inorganic barrier layer 401, except for the area corresponding to the O-shaped perforated region 1. The organic barrier layer 401 can release stress. After that, the second inorganic barrier layer 403 is manufactured on the organic barrier layer 402. The second inorganic barrier layer 403 covers the organic barrier layer 402 and the O-shaped perforated region 1.

As shown in FIG. 6, a through hole is formed by removing all the film layers in the O-shaped perforated region 1 by laser cutting. That is, the O-shaped perforated region 1 has a through hole penetrating the OLED display.

An embodiment of the present invention further provides a method for manufacturing an OLED display, which includes:

S1, forming a barrier layer on a substrate, the substrate having a display region, a perforated region and a non-display region located between the display region and the perforated region;

S2, forming a reversed trapezoid structure on the barrier layer in the non-display region;

S3, manufacturing a thin-film transistor driving circuit in the display region of the substrate, the TFT driving circuit including a plurality of TFT electrodes surrounding a through hole and forming an opening in the non-display region;

S4, forming an insulating layer on the TFT driving circuit, the insulating layer forming the opening in the non-display region;

S5, forming an organic light-emitting layer on the insulating layer, the organic light-emitting layer breaking at the reversed trapezoid structure to form a discontinuous film layer, the organic light-emitting layer forming the opening in the non-display region; and

S6, covering the TFT driving circuit, the insulating layer and the organic light-emitting layer with an encapsulating layer.

In the OLED display provided in the present invention, the reversed trapezoid structure is obtained by etching the barrier layer in the perforated region by exposure and development processes. A thickness of the barrier layer is ranged from 0.5 to 1 micrometer. The angle θ of the reversed trapezoid structure is ranged from 120 to 150 degrees. During manufacturing the organic light-emitting layer in later processes, a thickness of the organic layer does not exceed 0.3 micrometer and cannot cover the reversed trapezoid step, and instead, will form discontinuous sections at the reversed trapezoid structure. Accordingly, it greatly lowers manufacturing difficulty since there is no need to design a mask having an opening to avoid the perforated region in coating the organic layer by evaporation. Meanwhile, the discontinuous film layer formed at the reversed trapezoid structure by the organic light-emitting layer can prevent from a lateral invasion of moisture.

Hereinbefore, an OLED display and a manufacturing method thereof provided in the embodiments of the present application are introduced in detail, the principles and implementations of the embodiments are set forth herein with reference to specific examples, descriptions of the above embodiments are merely served to assist in understanding the technical solutions and essential ideas of the present application. Those having ordinary skill in the art should understand that they still can modify technical solutions recited in the aforesaid embodiments or equivalently replace partial technical features therein; these modifications or substitutions do not make essence of corresponding technical solutions depart from the spirit and scope of technical solutions of embodiments of the present application.

1. An organic light emitting diode (OLED) display, comprising:
a substrate;
a barrier layer, disposed on the substrate, the barrier layer and the substrate having a through hole penetrating the barrier layer and the substrate, the barrier layer having a reversed trapezoid structure;
a thin-film transistor (TFT) driving circuit, disposed on the barrier layer, the TFT driving circuit comprising a plurality of TFT electrodes surrounding the through hole, the TFT driving circuit having no TFT electrodes in the through hole;
an insulating layer, disposed on the TFT driving circuit, the insulating layer comprising an opening for exposing the through hole;
an organic light-emitting layer, disposed on the insulating layer; and
an encapsulating layer, disposed on the organic light-emitting layer,
wherein the organic light-emitting layer breaks at the reversed trapezoid structure to form a discontinuous film layer,
wherein a length of an upper edge of the reversed trapezoid structure is greater than a length of a lower edge of the reversed trapezoid structure, and a thickness of the organic light-emitting layer is less than a thickness of the reversed trapezoid structure.

2. The OLED display according to claim 1, wherein the substrate has a perforated region corresponding to the through hole, a display region corresponding to the TFT driving circuit and a non-display region located between the perforated region and the display region, and wherein the reversed trapezoid structure is located in the non-display region.

3. The OLED display according to claim 2, wherein the TFT driving circuit, the insulating layer and the organic light-emitting layer break at the reversed trapezoid structure to form an opening.

4. The OLED display according to claim 3, wherein the encapsulating layer completely covers the reversed trapezoid structure and the opening formed at the reversed trapezoid structure by the TFT driving circuit, the insulating layer and the organic light-emitting layer.

5. The OLED display according to claim 2, wherein a crack-preventing structure is disposed above the barrier layer and is located in the non-display region close to the perforated region.

6. The OLED display according to claim 5, wherein the crack-preventing structure and the insulating layer use a same material.

7. The OLED display according to claim 1, wherein a thickness of the reversed trapezoid structure is ranged from 0.5 to 1 micrometer and an angle θ inclined from a bottom of the reversed trapezoid structure is ranged from 120 to 150 degrees.

8. An organic light emitting diode (OLED) display, comprising:
a substrate;
a barrier layer, disposed on the substrate, the barrier layer and the substrate having a through hole penetrating the barrier layer and the substrate, the barrier layer having a reversed trapezoid structure;
a thin-film transistor (TFT) driving circuit, disposed on the barrier layer, the TFT driving circuit comprising a plurality of TFT electrodes surrounding the through hole, the TFT driving circuit having no TFT electrodes in the through hole;
an insulating layer, disposed on the TFT driving circuit, the insulating layer comprising an opening for exposing the through hole;
an organic light-emitting layer, disposed on the insulating layer; and
an encapsulating layer, disposed on the organic light-emitting layer,
wherein the organic light-emitting layer breaks at the reversed trapezoid structure to form a discontinuous film layer.

9. The OLED display according to claim 8, wherein the substrate has a perforated region corresponding to the through hole, a display region corresponding to the TFT driving circuit and a non-display region located between the perforated region and the display region, and wherein the reversed trapezoid structure is located in the non-display region.

10. The OLED display according to claim 9, wherein the TFT driving circuit, the insulating layer and the organic light-emitting layer break at the reversed trapezoid structure to form an opening.

11. The OLED display according to claim 10, wherein the encapsulating layer completely covers the reversed trapezoid structure and the opening formed at the reversed trapezoid structure by the TFT driving circuit, the insulating layer and the organic light-emitting layer.

12. The OLED display according to claim 9, wherein a crack-preventing structure is disposed above the barrier layer and is located in the non-display region close to the perforated region.

13. The OLED display according to claim 12, wherein the crack-preventing structure and the insulating layer use a same material.

14. The OLED display according to claim 8, wherein a length of an upper edge of the reversed trapezoid structure is greater than a length of a lower edge of the reversed trapezoid structure.

15. The OLED display according to claim 14, wherein a thickness of the reversed trapezoid structure is ranged from 0.5 to 1 micrometer and an angle θ inclined from a bottom of the reversed trapezoid structure is ranged from 120 to 150 degrees.

16. The OLED display according to claim 8, wherein a thickness of the organic light-emitting layer is less than a thickness of the reversed trapezoid structure.

17. A method for manufacturing an organic light emitting diode (OLED)display, comprising:
S1, forming a barrier layer on a substrate, the substrate having a display region, a perforated region and a non-display region located between the display region and the perforated region;
S2, forming a reversed trapezoid structure on the barrier layer in the non-display region;
S3, manufacturing a thin-film transistor driving circuit in the display region of the substrate, the TFT driving circuit comprising a plurality of TFT electrodes surrounding a through hole and forming an opening in the non-display region;
S4, forming an insulating layer on the TFT driving circuit, the insulating layer forming the opening in the non-display region;
S5, forming an organic light-emitting layer on the insulating layer, the organic light-emitting layer breaking at the reversed trapezoid structure to form a discontinuous film layer, the organic light-emitting layer forming the opening in the non-display region; and
S6, covering the TFT driving circuit, the insulating layer and the organic light-emitting layer with an encapsulating layer.
